(19) United States
(12) Patent Application Publication
(10) Pub. No.: US 2021/0341516 A1
(43) Pub. Date: Nov. 4, 2021

(54) PROBE PIN AND INSPECTION MODULE

(71) Applicant: Richtek Technology Corporation, Zhubei City (TW)

(72) Inventor: Fang-Ling Chuang, Hsinchu (TW)

(21) Appl. No.: 17/210,459

(22) Filed: Mar. 23, 2021

Related U.S. Application Data
(60) Provisional application No. 63/017,008, filed on Apr. 29, 2020.

(30) Foreign Application Priority Data
Aug. 4, 2020 (TW) 109126320

(51) Int. Cl. G01R 1/067; G01R 31/28

(52) U.S. Cl. CPC G01R 1/06711; G01R 31/2887

(57) ABSTRACT

A probe pin includes: a reference axis extending along a longitudinal direction of the probe pin; a head portion, which includes, in a sequential order along the reference axis, a sensing end, at least one positioning recess, and a first spring engaging portion; a bottom portion, including a connecting end; and a spring, disposed between the top and bottom portions, wherein the spring encircles and engages with the first spring engaging portion, and abuts the bottom portion.

### CROSS REFERENCE

THE present invention claims priority to U.S. 63/017,008 filed on Apr. 29, 2020 and claims priority to TW 109126320 filed on Aug. 4, 2020.

### BACKGROUND OF THE INVENTION

### Field of Invention

The present invention relates to a probe pin, especially a probe pin for sensing and detecting an integrated circuit.

### Description of Related Art

In one prior art, the probe pin has a sharp end (FIG. 1). This sharp end design leads to troubles in testing, such as damaging or distorting the circuit pins of an integrated circuit, and the sharp end is easy to slip to cause an instant huge deviation of the test parameters, to cause sensing errors and even damage to the integrated circuit. The test by the probe pins is usually the final inspection step before shipment, so if the damage happens during this final step, the damaged integrated circuit may be shipped to a customer without being noticed, to adversely affect the vendor customer relationship.

The aforementioned prior art probe pins usually have large diameters, such as a probe diameter of 1 mm or higher. When the pitch between the sensing points on the integrated circuit becomes smaller and smaller, the probe size needs to be correspondingly reduced; hence, a prior art proposes probe pins with high slender ratios. However, such high slender ratio probe pins are easy to slip or distort when receiving an axial force, making the test results unstable.

In view of the above, the present invention provides a probe pin, wherein the probe pin does not distort the circuit pin of the integrated circuit, and the probe pin does not easily slip during the probe test, to significantly improve the test performance and reliability.

### SUMMARY OF THE INVENTION

In view of the above, the present invention discloses a probe pin, which includes: a reference axis extending along a longitudinal direction of the probe pin; a head portion, which includes, in a sequential order along the reference axis, a sensing end, at least one positioning recess, and a first spring engaging portion; a bottom portion, including a connecting end; and a spring, disposed between the top and bottom portions, wherein the spring encircles and engages with the first spring engaging portion, and abuts the bottom portion.

In one embodiment, the sensing end includes a multi-point-contact end, a line-contact end, or a surface-contact end. The sensing end is for use to abut a sensing point or an circuit pin of an integrated circuit for sensing (or detecting) the integrated circuit.

In another perspective, the present invention proposes an inspection module accommodating the probe pins provided by the present invention.

In one embodiment, an inspection module provided by the present invention includes: a plurality of probe pins, each of which includes a sensing end, a first spring engaging portion, a spring, and a connecting end, wherein the spring encircles and engages with the first spring engaging portion; a pin allocating plate, including a plurality of pin guiding holes which respectively correspond to a plurality of sensing points of an integrated circuit, wherein the sensing ends are configured to protrude out from the pin guiding holes, wherein the pin allocating plate further includes a tapering structure for guiding the integrated circuit to enter a predetermined position where the sensing ends are aligned with the sensing points; and a bottom plate, including a plurality of pinholes, corresponding to the positions of the pin guiding holes, the pinholes accommodating the probe pins, whereby the connecting ends protrude out from the bottom plate; wherein the sensing end includes a multi-point-contact end, a line contact end, or a surface contact end.

The connecting ends are configured to contact or to be coupled to a plurality of signal contacts of a test circuit.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a prior art probe pin of.

FIGS. 2A-2D and FIGS. 3 to 8 show schematic diagrams of the probe pins according to various embodiments of the present invention.

FIG. 9 shows the difference between the effect of the prior art probe pin and the effect of the present invention.

FIGS. 10 and 11 show schematic diagrams of inspection modules according to two embodiments of the present invention.

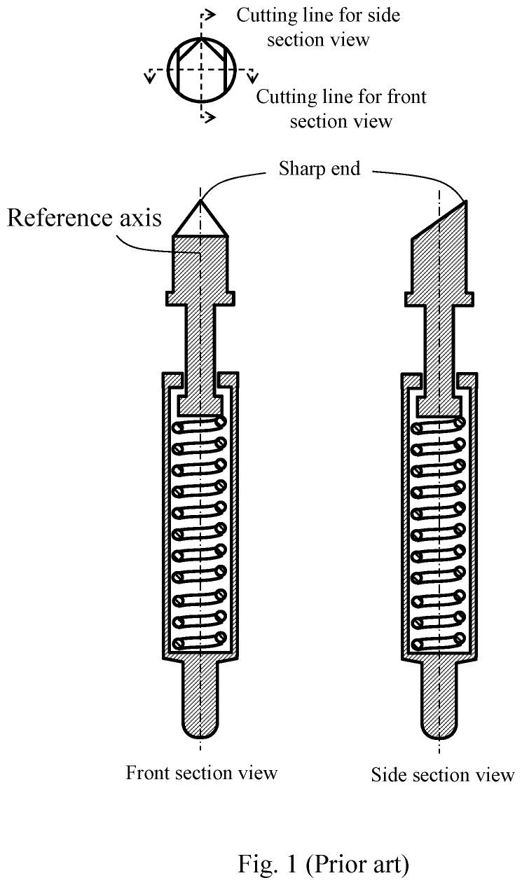

### DESCRIPTION OF THE PREFERRED EMBODIMENTS

The objectives, technical details, features, and effects of the present invention will be better understood with regard to the detailed description of the embodiments below, with reference to the drawings.

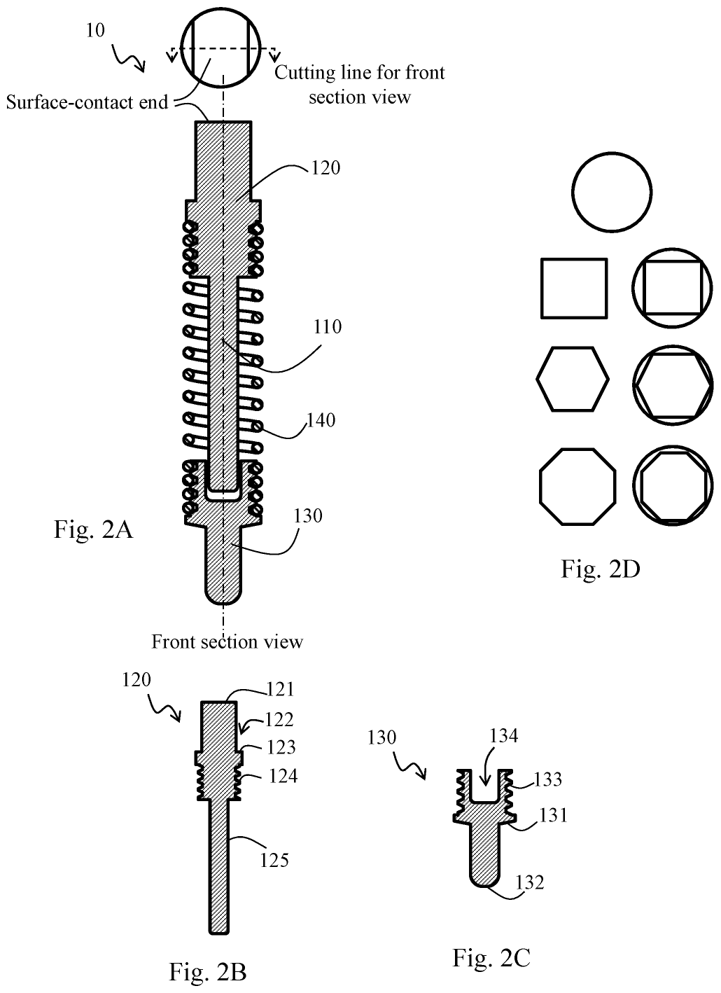

FIGS. 2A-2C show an embodiment of the present invention, wherein the probe pin 10 according to the present invention includes: a reference axis 110, extending along a longitudinal direction of the probe pin 10 and penetrating a central portion of the probe pin 10; a head portion 120, which includes, in a sequential order along the reference axis 110, a sensing end 121, at least one positioning recess 122, a top stopper portion 123 adjacent to the positioning recess 122, and a first spring engaging portion 124; a bottom portion 130, which includes, in a sequential order along the reference axis 110, a bottom stopper portion 131, and a connecting end 132; and a spring 140, disposed between the head portion 120 and the bottom portion 130, the spring 140 encircling and engaging with the first spring engaging portion 124 and abutting the bottom portion 130.

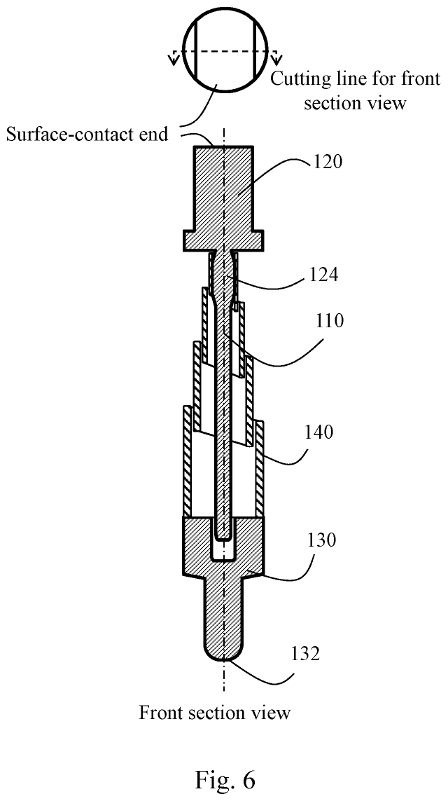

According to some embodiments of the present invention, the bottom portions 130 may optionally include second spring engaging portions 133 (FIGS. 2C, 3, 4, and 5). However, in some other embodiments of the present invention (FIGS. 6, 7, and 8), the second spring engaging portions can be omitted. Whether the second spring engaging portions are provided or not may be determined according to the design of the probe pins, or the operational relationship between the probe pin and the inspection module.

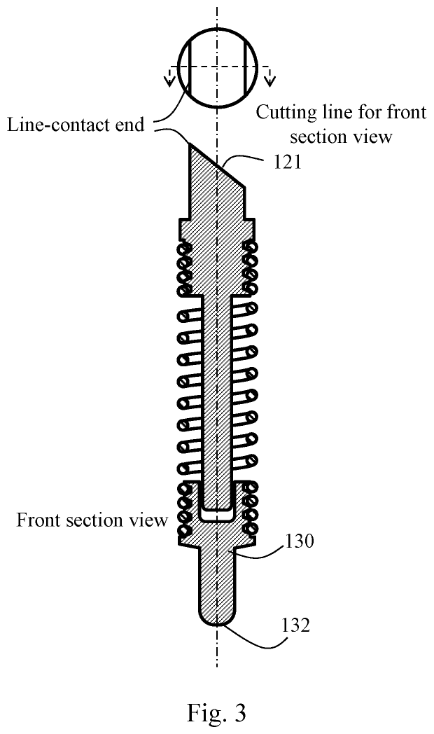

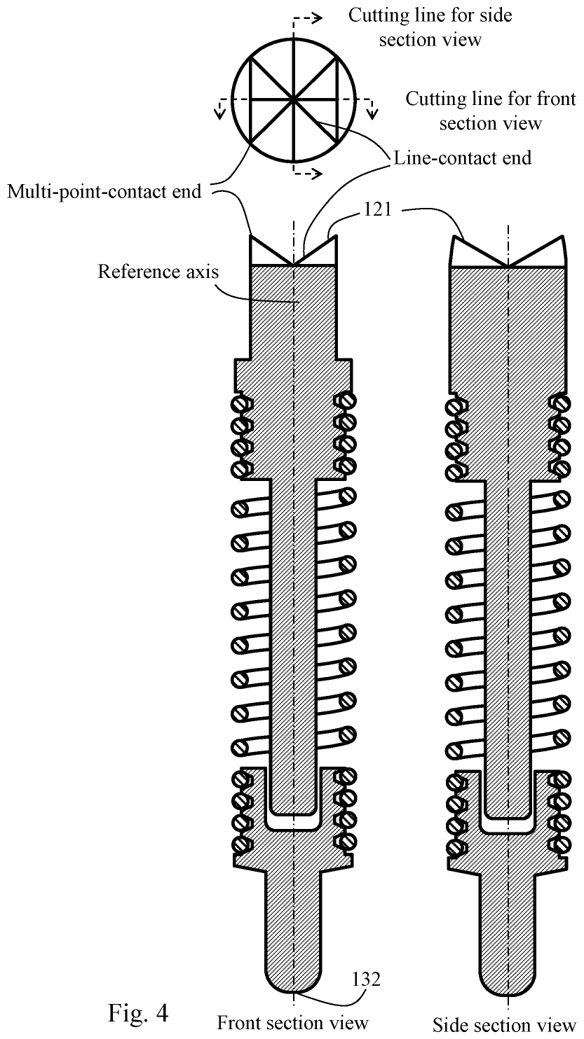

The sensing end 121 can be embodied in many forms, such as a surface-contact end (FIG. 2A), a line-contact end (FIG. 3), or a multi-point-contact end (FIG. 4). The sensing end 121 is for use to contact a sensing point or an circuit pin of an integrated circuit, to sense or detect the integrated circuit. The sensing end 121 is different from prior art in that the sensing end 121 greatly increases the contact (or abutment) area, so it avoids excessive force concentrated on one contact point of the circuit pin to damage the circuit pin, and it also increases the friction force between the probe pin and the circuit pin, to reduce the possibility of slipping. Among these embodied forms, for example, compared to the surface-contact end, the line-contact end can be used for circuit pins having a smaller contact area and smaller pitch for more accurate contact.

In one preferred embodiment shown in FIG. 4, the sensing end 121 can serve for different purposes to have different contact patterns. For example, when the sensing end 121 touches a plane surface, it forms a multi-point contact. When the sensing end 121 contacts a spherical surface or an arc surface (for example, a ball grid array package pin, i.e. BGA pin), it forms a multi-line contact or a multi-surface contact. In any of the above cases, the contact between the probe pin and the circuit pin is not just on one point.

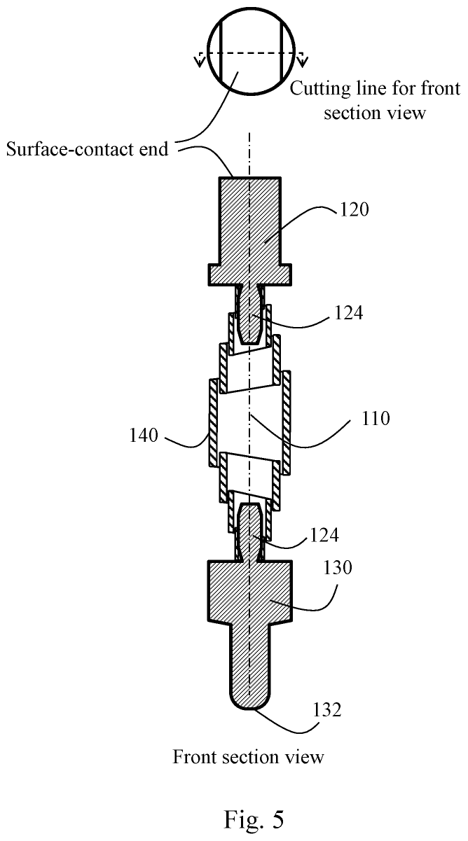

In the embodiments of the present invention, the spring 140 can be a helical spring (FIGS. 2, 3, and 4) or a volute spring (FIGS. 5, 6, and 7). The spring 140 is located to engage with the first spring engaging portion 124 of the head portion 120, which can be a screw type engaging portion (FIGS. 2A, 3, and 4), or a shuttle type engaging portion (FIGS. 5, 6, and 7). Note that the spiral spring does not necessarily have to engage with a screw type engaging portion, but also can engage with a shuttle type engaging portion. When the head portion 120 and the bottom portion 130 both have engaging portions (the first and second spring engaging portions 124 and 133) to engage with the spring 140, the first and second spring engaging portions 124 and 133 can both be the screw type, or both be the shuttle type, or they are a combination of the shuttle type and the screw type; for example, the first spring engaging portion 124 is the shuttle type and the second spring engaging portion 133 is the screw type, or, the first spring engaging portion 124 is the screw type and the second spring engaging portion 133 is the shuttle types. Regardless whether a helical spring or the volute spring is used, a suitable material can be selected to provide suitable mechanical properties required for the sensing end to provide an appropriate compression force (for example: 30 gf). The material for example can include stainless steel, copper alloy, etc.

In the probe pin of the present invention, the spring is designed to be substantially exposed, which provide an advantage that the diameter of the probe pin can be very small, such as 0.3 mm or even less (for example, 0.2 mm). In this diameter, the probe pin can still be allowed to have a certain compressible range along the reference axis, and this compressible range will not result in slip transversely (in a direction perpendicular to the reference axis) under compression force. Therefore, the design of the present invention can greatly increase the sensing stability of the probe pin.

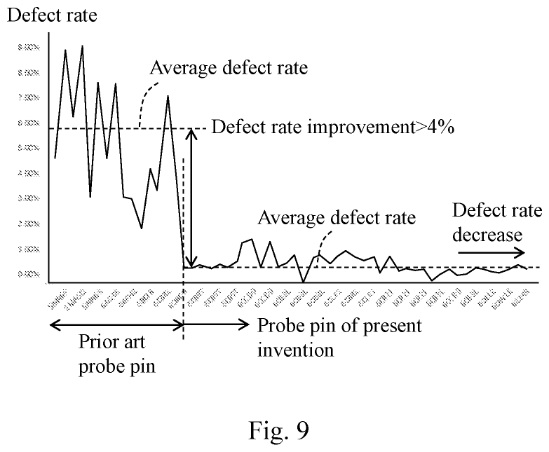

In the present invention, the size of the probe pin can be greatly reduced, while the probe pin still has a stable resistance, inductance, and capacitance. Therefore, the sensing errors can be greatly reduced. Please refer to FIG. 9, which shows sensing results by the probe pins of the prior art and the probe pin of the present invention, onto the same type of integrated circuit of different batches. The defect rate of the probe pins of the present invention is significantly improved over the prior art. The example shown in FIG. 9 shows an early example of the present invention wherein the probe pins of the present invention are initially used. The defect rate is even more decreased after several batches with fine adjustment and more familiarity, and the improvement is even more over the prior art. Therefore, it is proven that the present invention does improve the defect rate over the prior art.

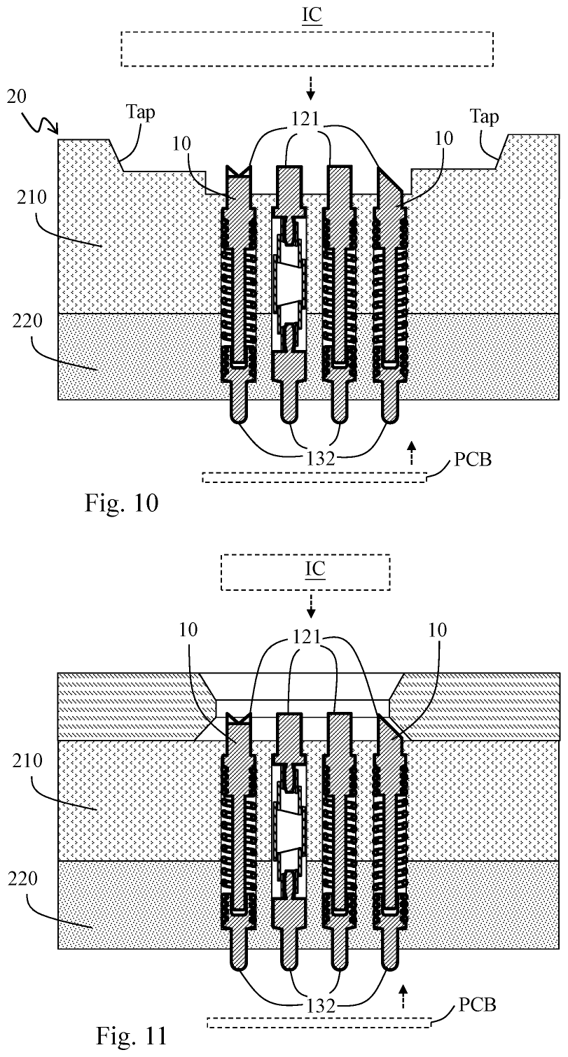

In the present invention, regardless of whether a spiral spring or a volute spring is used, the spring can help to form a conduction path between the head portion 120 and the bottom portion 130, to couple the sensing point of the integrated circuit IC to the signal contact of a test circuit PCB (referring to FIGS. 10 and 11). The volute spring has a structure formed by rotating a plate-shaped material, so it has a larger surface area than the spiral spring, and therefore a lower surface resistance as compared to that of the spiral spring. In addition, the process of engaging the spring into the screw type engaging portion, is different from engaging the spring into the shuttle type engaging portion. For example, when the spring is engaged into the screw type engaging portion, it is necessary to rotate the spring several rounds around the screw type engaging portion to fix the spring. On the other hand, when the spring is engaged into the shuttle type engaging portion, the spring is pushed sequentially through a small section, a large section, and a small section of the shuttle structure of the shuttle type engaging portion, such that the spring is fit into a desired position where it has a low contact resistance between the spring and the shuttle type engaging portion.

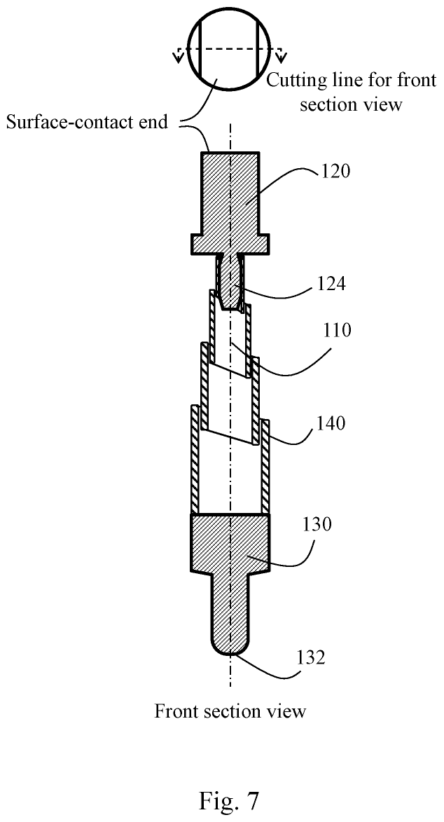

Please refer to FIG. 2B, in one embodiment, the head portion 120 further includes a central axle 125, and the bottom portion 130 includes a central hole 134. The central axle 125 of the probe pin 10 is configured to be aligned with and inserted into the central hole 134. The spring 140 encircles the central axle 125. The central hole 134 is located inside and encircled by the second spring engaging portion 133. The central axle 125 is an optional component and it can be omitted in some embodiments, such as the embodiments shown in FIGS. 5 and 7, wherein the spring 140 is exposed to the outside of the probe pin 10, but not encircling the central axle 125 as in other embodiments. That is, in the case that the probe pin 10 includes the central axle 125, the conduction between the head portion 120 and the bottom portion 130 can be achieved by the central axle 125 plus the spring 140; in the case that the probe pin 10 does not include the central axle 125, the conduction between the head portion 120 and the bottom portion 130 can be achieved by the spring 140.

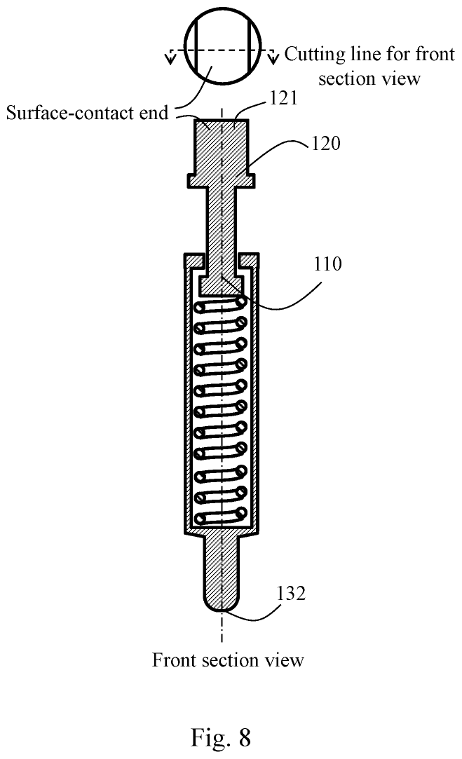

According to the present invention, the sensing end 121 can include a surface contact end, a line contact end, or a multi-point-contact end, in combination with a spiral spring or a volute spring, wherein the spiral spring or volute spring can be exposed to the outside of the probe pin (FIGS. 2A and 3-7) or accommodated within a housing (referring to FIG. 8), to encircle a central axle, or without a central axle.

In one embodiment of the present invention, the head portion 120, the spring 140, and the bottom portion 130 are separate components, for easy maintenance and replacement, so that it is not required to disassemble or replace the whole set during maintenance and repair.

From another perspective, the present invention also provides an inspection module for accommodating the aforementioned probe pins therein.

Please refer to FIGS. 10 and 11, in one embodiment, the inspection module 20 provided by the present invention includes a plurality of probe pins 10, a pin allocating plate 210, and a bottom plate 220. Each of the probe pins 10 includes a sensing end 121 and a connecting end 132. The plurality of probe pins 10 can be of the same or different types, as described in the previous embodiments, and FIGS. 10 and 11 show that different types of probe pins 10 are used, as an example. The pin allocating plate 210 includes a plurality of pin guiding holes (as shown in the figures) which respectively correspond to a plurality of sensing points of an integrated circuit IC, and the pin guiding holes allow the sensing ends to protrude out from the pin guiding holes to contact the sensing points of the integrated circuit IC. The pin allocating plate 210 further includes a tapering structure Tap, which can be apart of the pin allocating plate 210 (FIG. 10), or can be a separate component on or above the pin allocating plate 210, to assist the integrated circuit IC to be placed into a predetermined position for aligning the sensing ends 121 to the sensing points of the integrated circuit IC. The bottom plate 220 includes a plurality of pinholes corresponding to the pin guiding holes, wherein the pinholes are configured to accommodate the probe pins 10, so that the connecting ends 132 protrude from the bottom plate 220 to contact the test circuit PCB. As mentioned above, the sensing end 121 may include a multi-point-contact end, a line-contact end, or a surface-contact end.

The aforementioned integrated circuit package can include: BGA, WDFN, LQFP, QFN and other package specifications. Users can determine the required type and shape of the probe pins according to the test requirements.

In one embodiment, when viewing the probe pin 10 along the reference axis 110 (that is, in a cross section view perpendicular to the reference axis observed from the head portion 120), an outline geometry of the sensing end 121 for example can be: circle with at least one cutting side (FIG. 2A), circle, hexagonal or any other polygonal shape (FIG. 2D). The inspection module 20 accommodating probe pins 10 may also have pin guiding holes of a corresponding shape; for example, circle with at least one cutting side, circle, hexagonal or any other polygonal shape, etc. However, in another embodiment, the shape of the pin guiding holes accommodating the sensing ends 121 can have a shape which does not correspond to the outline geometry of the contact end, as long as the pin guiding holes can provide a space for the probe pins to penetrate and protrude out for sensing (or inspection) the sensing points on the integrated circuit.

In one embodiment, the positioning recess 122 and a top stopper portion 123 adjacent to the positioning recess 122 can be used to guide the head portion 120 to insert into the pin guiding hole of the inspection module 20, whereby the sensing end 121 can protrude from the inspection module 20 to sense the integrated circuit IC. The top stopper portion 123 can limit the protruding height of the sensing end 121, so as not to push the integrated circuit IC too high, lest other sensing ends 121 lose signal contact with the integrated circuit IC. In one embodiment, the top stopper portion 123 can limit the protruding height of all the sensing ends 121, so that all the sensing ends appropriately contact or are appropriately coupled to the signal contacts on the integrated circuit IC. On the other side of the inspection module 20, the connecting ends 132 are configured to contact or to be coupled to the signal contacts on the test circuit PCB, for analyzing the information from the integrated circuit IC. In another embodiment, the coupling connection between the connecting ends 132 and the test circuit PCB is not limited to physical contact, but can be electrically connected by wiring, etc. The variations all fall within the scope of the present invention.

The present invention has been described in considerable detail with reference to certain preferred embodiments thereof. It should be understood that the description is for illustrative purpose, not for limiting the scope of the present invention. For one example, the number of the turns of the engaging portion can be modified and it still falls within the spirit of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention.

What is claimed is:

1. A probe pin, comprising:
a reference axis extending along a longitudinal direction of the probe pin;
a head portion, which includes, in a sequential order along the reference axis, a sensing end, at least one positioning recess, and a first spring engaging portion;
a bottom portion, including a connecting end; and
a spring, disposed between the top and bottom portions, wherein the spring encircles and engages with the first spring engaging portion, and abuts the bottom portion.

2. The probe pin of claim 1, wherein the sensing end includes a multi-point-contact end, a line-contact end, or a surface-contact end.

3. The probe pin of claim 2, wherein in a cross section view perpendicular to the reference axis, the surface-contact end is a circular shape, a hexagonal shape, or a polygonal shape other than hexagonal shape.

4. The probe pin of claim 1, wherein the head portion further includes a top stopper portion, and wherein the at least one positioning recess and the top stopper portion are configured to guide the head portion to insert into a pin guiding hole of an inspection module, whereby the sensing end protrudes out from the inspection module for sensing an integrated circuit.

5. The probe pin of claim 1, wherein the spring is a spiral spring or a volute spring.

6. The probe pin of claim 5, wherein the bottom portion includes a second spring engaging portion, and the spring encircles the second spring engaging portion; wherein the first and second spring engaging portions belong to a screw type, a shuttle type, or a combination of the shuttle type and the screw type, which is configured to operably engage with the spring.

7. The probe pin of claim 1, wherein the head portion further includes a central axle, and the bottom portion further includes a center hole, wherein a portion of the central axle is inserted into the central hole, and the spring encircles the central axle.

8. An inspection module, comprising:
a plurality of probe pins, each of which includes a sensing end, a first spring engaging portion, a spring, and a connecting end, wherein the spring encircles and engages with the first spring engaging portion;
a pin allocating plate, including a plurality of pin guiding holes which respectively correspond to a plurality of sensing points of an integrated circuit, wherein the sensing ends are configured to protrude out from the pin guiding holes, wherein the pin allocating plate further includes a tapering structure for guiding the integrated circuit to enter a predetermined position where the sensing ends are aligned with the sensing points; and
a bottom plate, including a plurality of pinholes, corresponding to the positions of the pin guiding holes, the pinholes accommodating the probe pins, whereby the connecting ends protrude out from the bottom plate;
wherein the sensing end includes a multi-point-contact end, a line contact end, or a surface contact end.

9. The inspection module of claim 8, wherein the connecting ends are configured to contact or to be coupled to a plurality of signal contacts of a test circuit.

10. The inspection module of claim 8, wherein the spring is a spiral spring or a volute spring.

11. The inspection module of claim 8, wherein the probe pin further includes a second spring engaging portion, and the first and second spring engaging portions belong to a screw type, a shuttle type, or a combination of the shuttle type and the screw type, which is configured to operably engage with the spring.
